(19) United States
(12) Patent Application Publication
(10) Pub. No.: US 2014/0206177 A1
(43) Pub. Date: Jul. 24, 2014

(54) WAFER PROCESSING METHOD

(71) Applicant: Disco Corporation, Tokyo (JP)

(72) Inventors: Yuki Ogawa, Tokyo (JP); Nobuyasu Kitahara, Tokyo (JP); Kentaro Odanaka, Tokyo (JP); Yukinobu Ohura, Tokyo (JP)

(73) Assignee: Disco Corporation, Tokyo (JP)

(21) Appl. No.: 14/151,071

(22) Filed: Jan. 9, 2014

(30) Foreign Application Priority Data
Jan. 23, 2013 (JP) 2013-010453

(51) Int. Cl. H01L 21/78

(52) U.S. Cl. CPC H01L 21/78
USPC 438/462

(57) ABSTRACT

A wafer processing method divides a wafer into individual devices along crossing streets formed on the front side of the wafer. The wafer has a substrate and a functional layer formed on the substrate, the individual devices being formed from the functional layer and partitioned by the streets. In a functional layer dividing step, a laser beam is applied along both sides of each street to form two parallel grooves. Each groove reaches the substrate, thereby dividing the functional layer. In a division groove forming step, a division groove is formed in the functional layer and the substrate along each street so that the division groove extends between the two grooves. The wavelength of the laser beam in the functional layer dividing step is 300 nm or less, at an absorption wavelength of a passivation film.

### BACKGROUND OF THE INVENTION

1. Field of the Invention

The present invention relates to a wafer processing method for dividing a wafer into a plurality of individual devices along a plurality of crossing streets formed on the front side of the wafer, the wafer being composed of a substrate and a functional layer formed on the front side of the substrate, the individual devices being formed from the functional layer and partitioned by the streets.

2. Description of the Related Art

As well known in the art, in a semiconductor device fabrication process, a functional layer composed of an insulating film and a functional film is formed on the front side of a substrate such as a silicon substrate, and a plurality of devices such as ICs and LSIs are formed like a matrix from this functional layer, thus obtaining a semiconductor wafer having the plural devices. The plural devices are partitioned by a plurality of division lines called streets formed on the front side of the semiconductor wafer. The semiconductor wafer is divided along these streets to obtain the individual devices.

In recent years, a semiconductor wafer intended to improve the processing performance of semiconductor chips (devices) such as ICs and LSIs has been put into practical use. This semiconductor wafer is composed of a substrate such as a silicon substrate and a functional layer formed on the front side of the substrate, wherein the functional layer is composed of a low-permittivity insulator film (Low-k film) and a functional film formed on the Low-k film, the functional film forming a plurality of circuits. Thus, the semiconductor devices are formed from the functional layer. The Low-k film is formed from an inorganic film of SiOF, BSG (SiOB), etc. or an organic film such as a polymer film of polyimide, parylene, etc.

Division of such a semiconductor wafer along the streets is usually performed by using a cutting apparatus called a dicing saw. This cutting apparatus includes a chuck table for holding the semiconductor wafer as a workpiece, cutting means for cutting the semiconductor wafer held on the chuck table, and moving means for relatively moving the chuck table and the cutting means. The cutting means includes a rotating spindle adapted to be rotated at high speeds and a cutting blade mounted on the rotating spindle. The cutting blade is composed of a disk-shaped base and an annular cutting edge mounted on one side surface of the base along the outer circumference thereof. The annular cutting edge is an electroformed diamond blade formed by bonding diamond abrasive grains having a grain size of about 3 μm, for example.

However, the Low-k film mentioned above is different in material from the substrate of the semiconductor wafer, so that it is difficult to cut the substrate together with the Low-k film by using the cutting blade. That is, the Low-k film is very brittle like mica. Accordingly, when the semiconductor wafer having the Low-k film is cut along the streets by using the cutting blade, there arises a problem such that the Low-k film may be separated and this separation may reach the devices to cause fatal damage to the devices.

To solve this problem, Japanese Patent Laid-open No. 2005-142398 discloses a wafer dividing method including the steps of applying a laser beam along both sides of each street on a semiconductor wafer to form two laser processed grooves along each street, thereby dividing a stacked layer, and next positioning a cutting blade between the outer side walls of the two laser processed grooves along each street to relatively move the cutting blade and the semiconductor wafer, thereby cutting the semiconductor wafer along each street.

### SUMMARY OF THE INVENTION

However, when the two laser processed grooves are formed along each street of the semiconductor wafer by applying a laser beam along both sides of each street as in the wafer dividing method described in Japanese Patent Laid-open No. 2005-142398, there arises a problem such that the functional layer may be separated in each device to cause a degradation in quality of each device. In more detail, a passivation film such as SiO₂, SiO, SiN, and SiNO films is formed on the front side of the functional layer. Accordingly, when a laser beam is applied to the functional layer from the upper side thereof, the laser beam passes through the passivation film to reach the inside of the functional layer. As a result, heat is generated by the application of the laser beam to the functional layer and this heat is temporarily confined in the functional layer by the passivation film, so that there is a possibility of separation of the functional layer in the area where the circuits are formed and the density is low.

It is therefore an object of the present invention to provide a wafer processing method which can divide a wafer into the individual devices along the streets without the separation of a functional layer in each device, wherein the wafer includes a substrate and the functional layer formed on the front side of the substrate and the devices are formed from this functional layer.

In accordance with an aspect of the present invention, there is provided a wafer processing method for dividing a wafer into a plurality of individual devices along a plurality of crossing streets formed on the front side of the wafer, the wafer being composed of a substrate and a functional layer formed on the front side of the substrate, the individual devices being formed from the functional layer and partitioned by the streets, the wafer processing method including a functional layer dividing step of applying a laser beam along both sides of each street of the wafer to form two laser processed grooves spaced in parallel to each other, each laser processed groove having a depth reaching the substrate, thereby dividing the functional layer; and a division groove forming step of forming a division groove in the functional layer and the substrate along each street so that the division groove extends along the center line between the two laser processed grooves formed along each street, wherein the wavelength of the laser beam to be applied in the functional layer dividing step is set to 300 nm or less that is an absorption wavelength to a passivation film.

Preferably, the division groove forming step includes the step of applying a laser beam along the center line between the two laser processed grooves formed along each street, thereby forming the division groove in the functional layer and the substrate along each street. Preferably, the wavelength of the laser beam to be applied in the functional layer dividing step is set to 266 nm, and the wavelength of the laser beam to be applied in the division groove forming step is set to 532 nm.

As described above, the wafer processing method according to the present invention includes the functional layer dividing step of applying a laser beam along both sides of each street of the wafer to form the two laser processed grooves spaced in parallel to each other, each laser processed groove having a depth reaching the substrate, thereby dividing the functional layer, and the division groove forming step of forming the division groove in the functional layer and the substrate along each street so that the division groove extends along the center line between the two laser processed grooves formed along each street, wherein the wavelength of the laser beam to be applied in the functional layer dividing step is set to 300 nm or less that is an absorption wavelength to a passivation film. Accordingly, when the laser beam is applied to the wafer, the passivation film formed on the front side of the functional layer is ablated instantaneously and does not confine the heat inside the functional layer, thereby eliminating the possibility of separation of the functional layer in the area where the circuits are formed and the density is low.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of a semiconductor wafer to be divided by the wafer processing method according to the present invention;

FIG. 1B is an enlarged sectional view of an essential part of the semiconductor wafer shown in FIG. 1A;

FIG. 2 is a perspective view showing a condition where the semiconductor wafer is attached to a dicing tape supported to an annular frame;

FIG. 3 is a perspective view of an essential part of a laser processing apparatus for performing a functional layer dividing step;

FIGS. 4A to 4C are views for illustrating the functional layer dividing step;

FIG. 5 is a graph showing the absorptivity of a passivation film in relation to the wavelength of a laser beam;

FIG. 6 is a perspective view of an essential part of a laser processing apparatus for performing a first preferred embodiment of a division groove forming step;

FIGS. 7A to 7C are views for illustrating the first preferred embodiment of the division groove forming step;

FIG. 8 is a perspective view of an essential part of a cutting apparatus for performing a second preferred embodiment of the division groove forming step; and

FIGS. 9A to 9D are views for illustrating the second preferred embodiment of the division groove forming step.

### DETAILED DESCRIPTION OF THE PREFERRED EMBODIMENTS

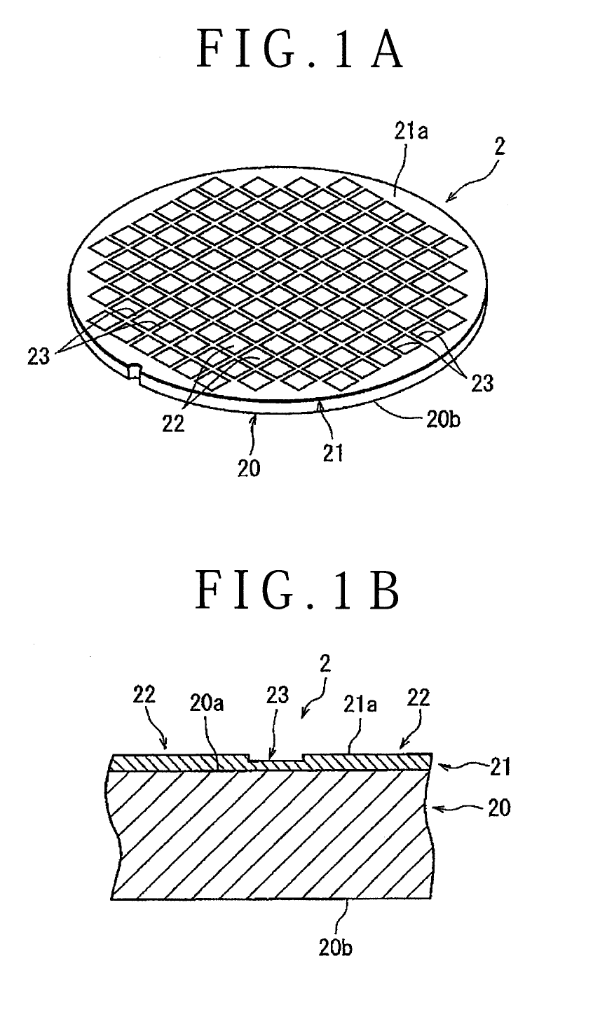

The wafer processing method according to the present invention will now be described in more detail with reference to the attached drawings. FIG. 1A is a perspective view of a semiconductor wafer 2 to be divided into individual devices by the wafer processing method according to the present invention, and FIG. 1B is an enlarged sectional view of an essential part of the semiconductor wafer 2 shown in FIG. 1A. As shown in FIGS. 1A and 1B, the semiconductor wafer 2 is composed of a substrate 20 such as a silicon substrate and a functional layer 21 formed on the front side 20a of the substrate 20. For example, the substrate 20 has a thickness of 140 μm. The functional layer 21 is composed of an insulating film and a functional film formed on the insulating film, the functional film forming a plurality of circuits. A plurality of devices 22 such as ICs and LSIs are formed like a matrix from the functional layer 21. These devices 22 are partitioned by a plurality of crossing streets 23 formed on the functional layer 21. In this preferred embodiment, the insulating film constituting the functional layer 21 is provided by an SiO₂ film or a low-permittivity insulator film (Low-k film). Examples of the Low-k film include an inorganic film of SiOF, BSG (SiOB), etc. and an organic film such as a polymer film of polyimide, parylene, etc. For example, the thickness of the insulating film is set to 10 μm. Further, a passivation film such as SiO₂, SiO, SiN, and SiNO films is formed on the front side of the functional layer 21.

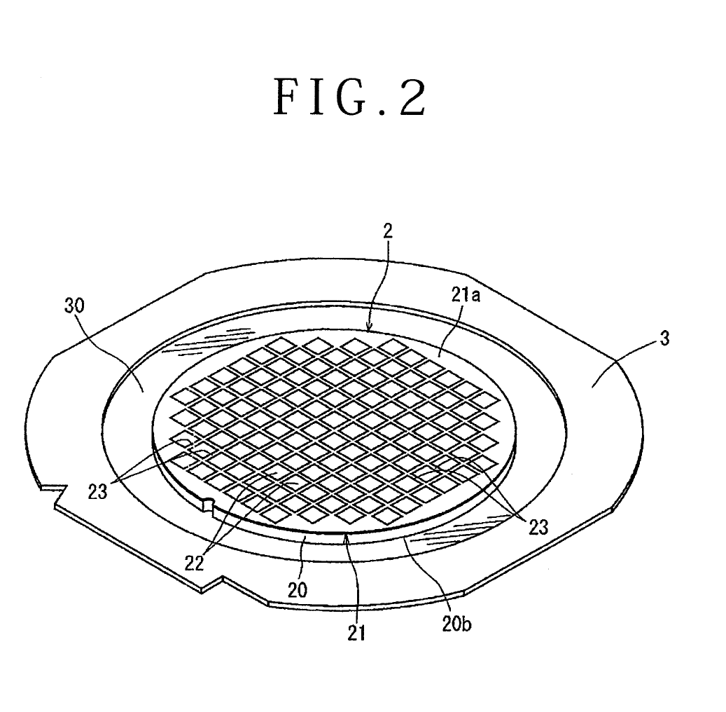

The wafer processing method for dividing the semiconductor wafer 2 along the streets 23 will now be described. First, a wafer supporting step is performed in such a manner that the back side 20b of the substrate 20 constituting the semiconductor wafer 2 is attached to a dicing tape supported to an annular frame. More specifically, as shown in FIG. 2, a dicing tape 30 is supported at its peripheral portion to an annular frame 3 so as to close the inside opening of the annular frame 3. The back side 20b of the substrate 20 constituting the semiconductor wafer 2 is attached to the front side (upper surface) of the dicing tape 30 supported to the annular frame 3. Accordingly, the semiconductor wafer 2 is supported through the dicing tape 30 to the annular frame 3 in the condition where the front side 21a of the functional layer 21, i.e., the front side of the semiconductor wafer 2 is oriented upward.

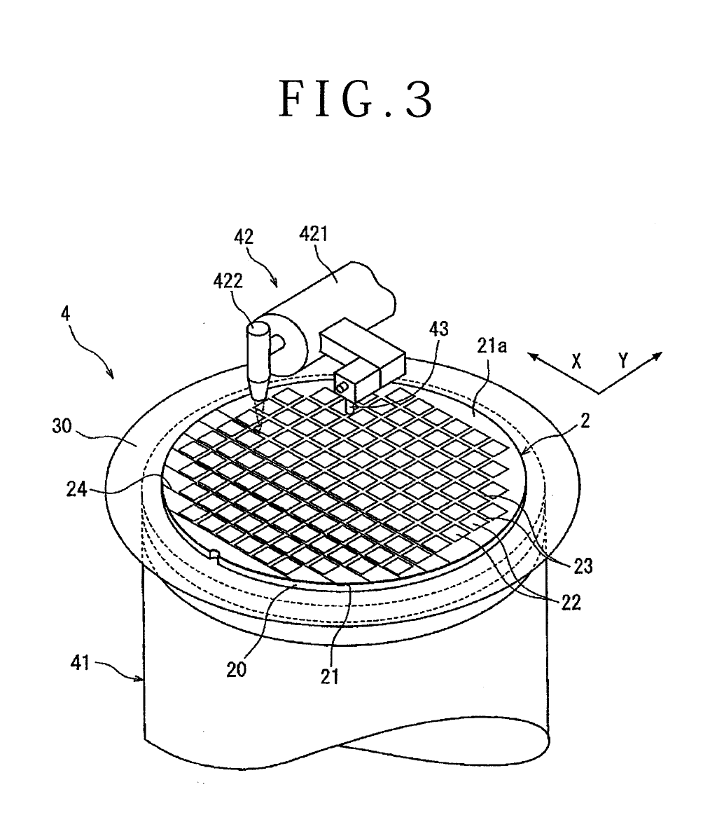

After performing the wafer supporting step mentioned above, a functional layer dividing step is performed in such a manner that a laser beam is applied along both sides of each street 23 of the semiconductor wafer 2 to form two laser processed grooves spaced in parallel to each other, each laser processed groove having a depth reaching the substrate 20, thereby dividing the functional layer 21. This functional layer dividing step is performed by using a laser processing apparatus 4 shown in FIG. 3. As shown in FIG. 3, the laser processing apparatus 4 includes a chuck table 41 for holding a workpiece, laser beam applying means 42 for applying a laser beam to the workpiece held on the chuck table 41, and imaging means 43 for imaging the workpiece held on the chuck table 41. The chuck table 41 has an upper surface as a holding surface for holding the workpiece thereon under suction. The chuck table 41 is movable both in the feeding direction shown by an arrow X in FIG. 3 by feeding means (not shown) and in the indexing direction shown by an arrow Y in FIG. 3 by indexing means (not shown).

The laser beam applying means 42 includes a cylindrical casing 421 extending in a substantially horizontal direction. Although not shown, the casing 421 contains pulsed laser beam oscillating means including a pulsed laser beam oscillator and repetition frequency setting means. The laser beam applying means 42 further includes focusing means 422 mounted on the front end of the casing 421 for focusing a pulsed laser beam oscillated by the pulsed laser beam oscillating means. The laser beam applying means 42 further includes focal position adjusting means (not shown) for adjusting the focal position of the pulsed laser beam to be focused by the focusing means 422.

The imaging means 43 is mounted on a front end portion of the casing 421 constituting the laser beam applying means 42 and includes illuminating means for illuminating the workpiece, an optical system for capturing an area illuminated by the illuminating means, and an imaging device (CCD) for imaging the area captured by the optical system. An image signal output from the imaging means 43 is transmitted to control means (not shown).

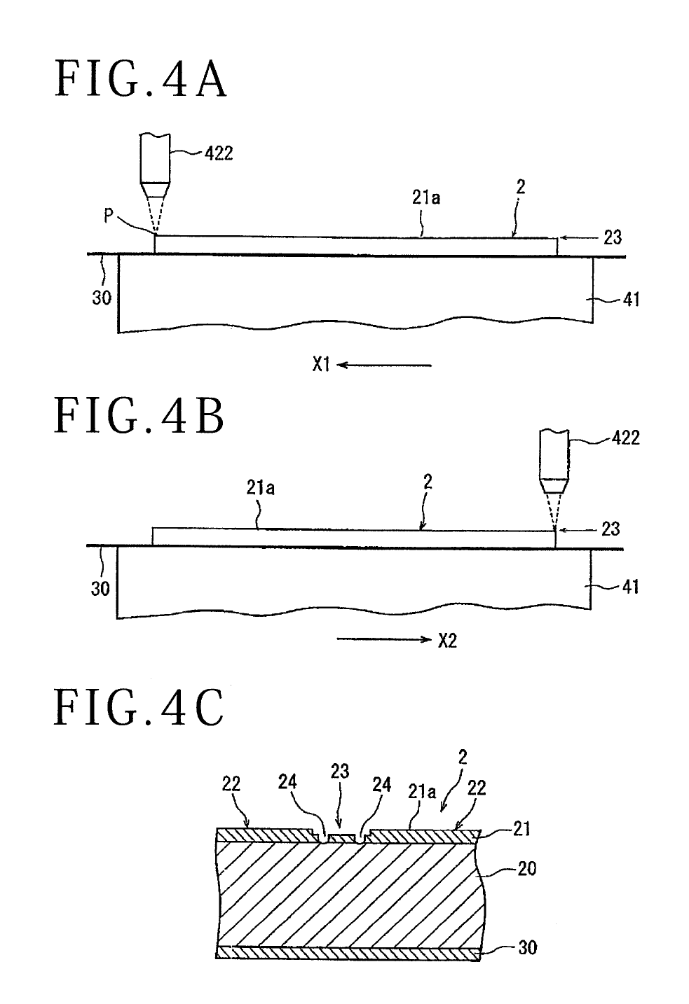

There will now be described with reference to FIG. 3 and FIGS. 4A to 4C the functional layer dividing step of applying a laser beam along both sides of each street 23 of the semiconductor wafer 2 by using the laser processing apparatus 4 mentioned above to form two laser processed grooves spaced in parallel to each other, each laser processed groove having a depth reaching the substrate 20, thereby dividing the functional layer 21. First, the semiconductor wafer 2 is placed on the chuck table 41 of the laser processing apparatus 4 in the condition where the dicing tape 30 attached to the semiconductor wafer 2 is in contact with the chuck table 41 as shown in FIG. 3. Thereafter, suction means (not shown) is operated to hold the semiconductor wafer 2 through the dicing tape 30 on the chuck table 41 under suction (wafer holding step). Accordingly, the front side 21a of the functional layer 21 of the semiconductor wafer 2 held on the chuck table 41 is oriented upward. Although the annular frame 3 supporting the dicing tape 30 is not shown in FIG. 3, the annular frame 3 is held by suitable frame holding means provided on the chuck table 41. Thereafter, the chuck table 41 holding the semiconductor wafer 2 is moved to a position directly below the imaging means 43 by operating the feeding means (not shown).

In the condition where the chuck table 41 is positioned directly below the imaging means 43, an alignment operation is performed by the imaging means 43 and the control means (not shown) to detect a subject area of the semiconductor wafer 2 to be laser-processed. More specifically, the imaging means 43 and the control means perform image processing such as pattern matching for making the alignment of the streets 23 extending in a first direction on the functional layer 21 of the semiconductor wafer 2 and the focusing means 422 of the laser beam applying means 42 for applying the laser beam to the wafer 2 along the streets 23, thus performing the alignment of a laser beam applying position (alignment step). Similarly, the alignment of a laser beam applying position is performed for the other streets 23 extending in a second direction perpendicular to the first direction on the functional layer 21.

After performing the alignment step mentioned above, the chuck table 41 is moved to a laser beam applying area where the focusing means 422 of the laser beam applying means 42 is located as shown in FIG. 4A, thereby positioning one end (left end as viewed in FIG. 4A) of a predetermined one of the streets 23 directly below the focusing means 422. Further, the focal point P of the pulsed laser beam to be applied from the focusing means 422 is set near the upper surface of the predetermined street 23 in this functional layer dividing step. Thereafter, the pulsed laser beam is applied from the focusing means 422 to the wafer 2, and the chuck table 41 is moved in the direction shown by an arrow X1 in FIG. 4A at a predetermined feed speed. When the other end (right end as viewed in FIG. 4B) of the predetermined street 23 reaches the position directly below the focusing means 422 as shown in FIG. 4B, the application of the pulsed laser beam is stopped and the movement of the chuck table 41 is also stopped.

Thereafter, the chuck table 41 is moved by 40 μm, for example, in the direction (indexing direction) perpendicular to the sheet plane of FIG. 4B. Thereafter, the pulsed laser beam is applied from the focusing means 422 to the wafer 2, and the chuck table 41 is moved in the direction shown by an arrow X2 in FIG. 4B at the predetermined feed speed. When the one end of the predetermined street 23 reaches the position shown in FIG. 4A, the application of the pulsed laser beam is stopped and the movement of the chuck table 41 is also stopped.

By performing this functional layer dividing step, two laser processed grooves 24 spaced in parallel to each other are formed along both sides of the predetermined street 23 so that each laser processed groove 24 has a depth larger than the thickness of the functional layer 21 in the street 23, i.e., a depth reaching the substrate 20 as shown in FIG. 4C. As a result, the functional layer 21 is divided by the two laser processed grooves 24. The functional layer dividing step mentioned above is similarly performed along all of the streets 23 formed on the semiconductor wafer 2.

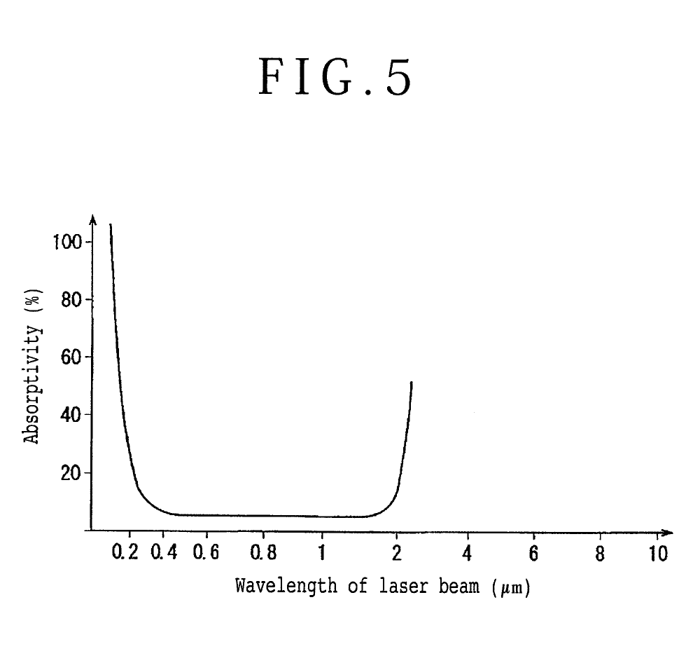

The passivation film is formed on the front side (upper surface) of the functional layer 21. Accordingly, when the pulsed laser beam is applied to the functional layer 21 from the upper side thereof, the pulsed laser beam passes through the passivation film to reach the inside of the functional layer 21. As a result, heat is generated by the application of the laser beam to the functional layer 21 and this heat is temporarily confined in the functional layer 21 by the passivation film, so that there is a possibility of separation of the functional layer 21 in the area where the circuits are formed and the density is low. To cope with this problem, the laser beam having a wavelength of 300 nm or less to be absorbed by the passivation film formed on the front side of the functional layer 21 is applied to the functional layer 21 in the functional layer dividing step according to the present invention. FIG. 5 shows the absorptivity of the passivation film in relation to the wavelength of the laser beam. In FIG. 5, the horizontal axis represents the wavelength of the laser beam and the vertical axis represents the absorptivity of the passivation film. As apparent from FIG. 5, when the wavelength of the laser beam becomes 300 nm or less, the absorptivity of the passivation film increases rapidly. Accordingly, it is important that the wavelength of the pulsed laser beam to be applied in the functional layer dividing step is set to 300 nm or less. As a result, when the laser beam having this specific wavelength is applied to the passivation film formed on the front side of the functional layer 21, the passivation film is ablated instantaneously and does not confine the heat inside the functional layer 21, thereby eliminating the possibility of separation of the functional layer 21 in the area where the circuits are formed and the density is low.

For example, the functional layer dividing step mentioned above is performed under the following processing conditions.

Wavelength of the laser beam: 266 nm

Pulse width: 12 ps

Repetition frequency: 200 kHz

Power: 2 W

Focused spot diameter: 10 μm

Work feed speed: 400 mm/s

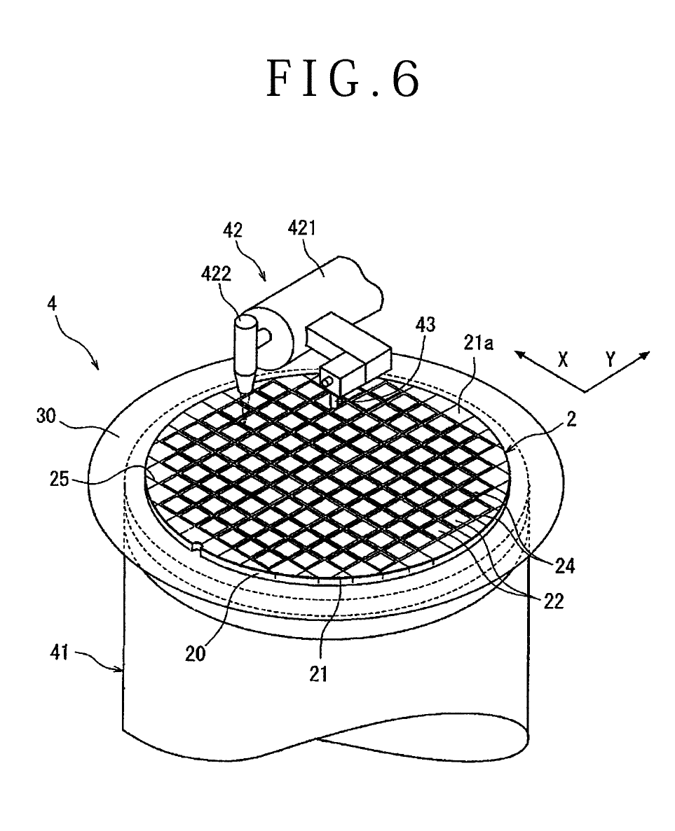

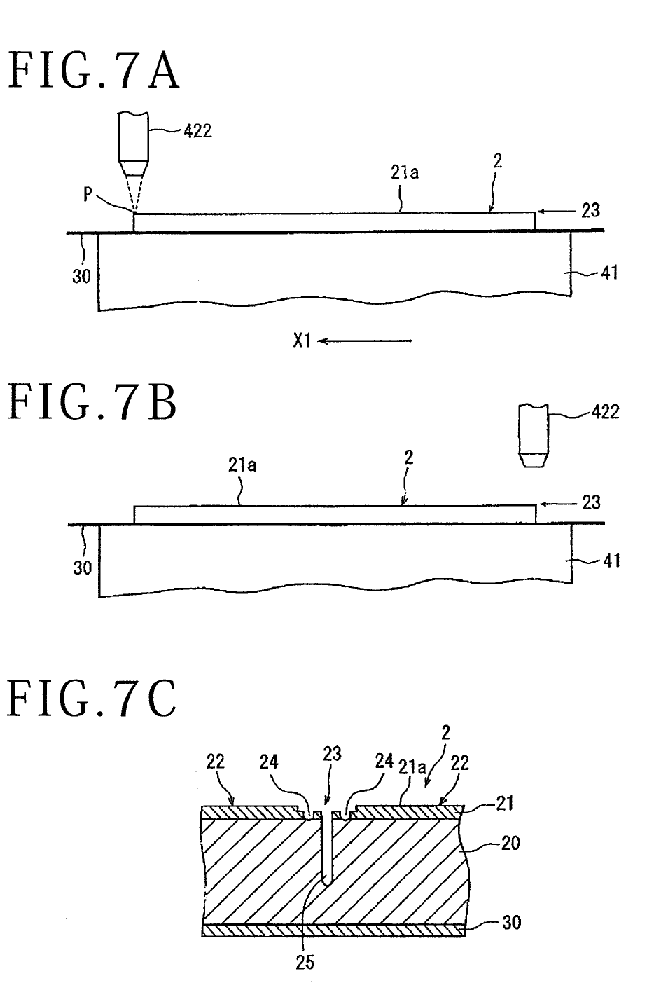

After performing the functional layer dividing step mentioned above, a division groove forming step is performed in such a manner that a division groove is formed in the functional layer 21 and the substrate 20 along each street 23 so as to extend along the center line between the two laser processed grooves 24 formed along each street 23. A first preferred embodiment of this division groove forming step will now be described with reference to FIG. 6 and FIGS. 7A to 7C.

The first preferred embodiment of the division groove forming step may be performed by using a laser processing apparatus similar to the laser processing apparatus 4 shown in FIG. 3. Such a similar laser processing apparatus is shown in FIG. 6 and the same reference numerals as those shown in FIG. 3 are used in FIG. 6 for convenience of illustration. In performing the first preferred embodiment of the division groove forming step, the semiconductor wafer 2 processed by the functional layer dividing step is placed on the chuck table 41 in the condition where the dicing tape 30 attached to the semiconductor wafer 2 is in contact with the chuck table 41 as shown in FIG. 6. Thereafter, suction means (not shown) is operated to hold the semiconductor wafer 2 through the dicing tape 30 on the chuck table 41 under suction (wafer holding step). Accordingly, the front side 21a of the functional layer 21 of the semiconductor wafer 2 held on the chuck table 41 is oriented upward. Although the annular frame 3 supporting the dicing tape 30 is not shown in FIG. 6, the annular frame 3 is held by suitable frame holding means provided on the chuck table 41. Thereafter, the chuck table 41 holding the semiconductor wafer 2 is moved to a position directly below the imaging means 43 by operating the feeding means (not shown). Thereafter, an alignment step is performed in the same manner as that mentioned above.

Thereafter, the chuck table 41 is moved to a laser beam applying area where the focusing means 422 of the laser beam applying means 42 is located as shown in FIG. 7A, thereby positioning a predetermined one of the streets 23 directly below the focusing means 422, wherein the center position between the two laser processed grooves 24 formed along the predetermined street 23 is set as a laser beam applying position where the laser beam is to be applied from the focusing means 422. At this time, one end (left end as viewed in FIG. 7A) of the predetermined street 23 is positioned directly below the focusing means 422. Further, the focal point P of the pulsed laser beam to be applied from the focusing means 422 is set near the upper surface of the predetermined street 23 in the division groove forming step. Thereafter, the pulsed laser beam is applied from the focusing means 422 to the wafer 2, and the chuck table 41 is moved in the direction shown by an arrow X1 in FIG. 7A at a predetermined feed speed. In this division groove forming step, the wavelength of the pulsed laser beam is set to an absorption wavelength to the substrate 20, and the power of the pulsed laser beam is set to a value larger than that in the functional layer dividing step. When the other end (right end as viewed in FIG. 7B) of the predetermined street 23 reaches the position directly below the focusing means 422 as shown in FIG. 7B, the application of the pulsed laser beam is stopped and the movement of the chuck table 41 is also stopped.

By performing the division groove forming step mentioned above, a division groove 25 having a predetermined depth is formed in the functional layer 21 and the substrate 20 at the center position between the two laser processed grooves 24 formed along the predetermined street 23 as shown in FIG. 7C. The functional layer 21 in each street 23 has already been divided by the two laser processed grooves 24 in the functional layer dividing step. Accordingly, even when the functional layer 21 in each street 23 is separated by applying the pulsed laser beam in the division groove forming step, this separation of the functional layer 21 has no influence on the outside of the two laser processed grooves 24, i.e., on the devices 22 side. Accordingly, the power of the pulsed laser beam can be increased to allow the formation of the division groove 25 having a predetermined depth for easy division of the wafer 2. The division groove forming step mentioned above is similarly performed along all of the streets 23 of the semiconductor wafer 2 processed by the functional layer dividing step.

For example, the division groove forming step mentioned above is performed under the following processing conditions.

Light source: YVO4 laser or YAG laser

Wavelength: 532 nm

Pulse width: 12 ps

Repetition frequency: 200 kHz

Power: 30 W

Focused spot diameter: 10 μm

Work feed speed: 400 mm/s

The semiconductor wafer 2 processed by the division groove forming step is transported to a dividing apparatus (not shown) for performing a dividing step as the next step. In the dividing step, the semiconductor wafer 2 can be easily divided into the individual devices 22 by mechanical breaking because the division groove 25 formed along each street 23 has a predetermined depth for easy division of the semiconductor wafer 2.

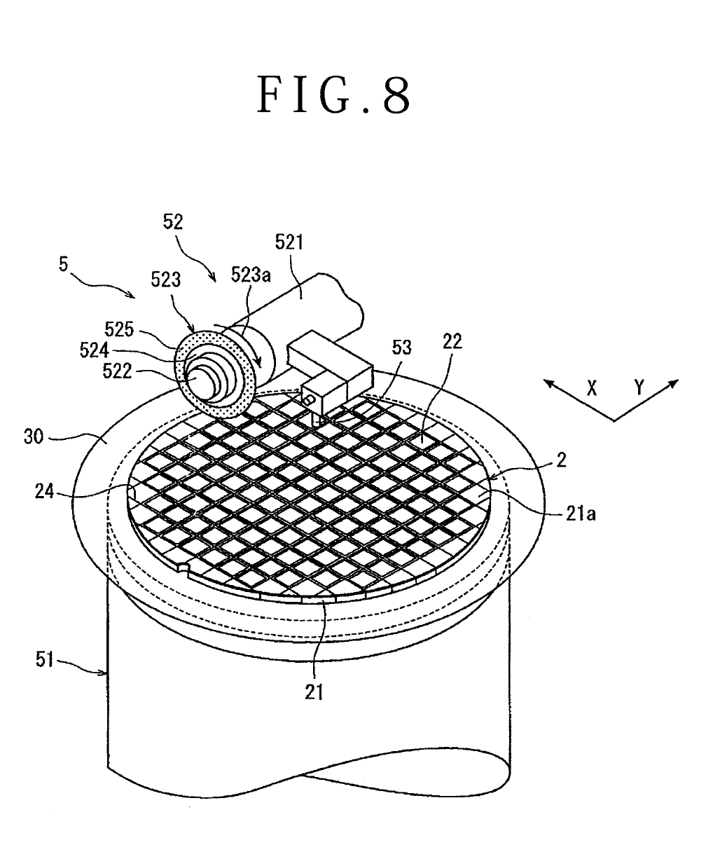

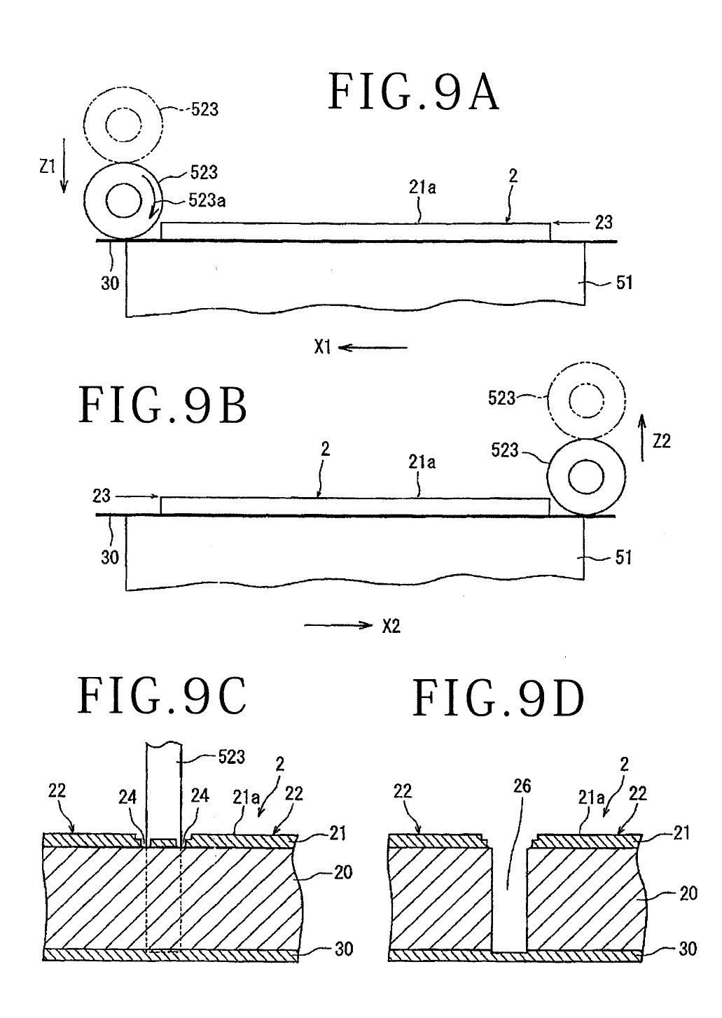

A second preferred embodiment of the division groove forming step will now be described with reference to FIG. 8 and FIGS. 9A to 9D. The second preferred embodiment of the division groove forming step is performed by using a cutting apparatus 5 shown in FIG. 8. As shown in FIG. 8, the cutting apparatus 5 includes a chuck table 51 for holding a workpiece, cutting means 52 for cutting the workpiece held on the chuck table 51, and imaging means 53 for imaging the workpiece held on the chuck table 51. The chuck table 51 has an upper surface as a holding surface for holding the workpiece thereon under suction. The chuck table 51 is movable both in the feeding direction shown by an arrow X in FIG. 8 by feeding means (not shown) and in the indexing direction shown by an arrow Y in FIG. 8 by indexing means (not shown).

The cutting means 52 includes a spindle housing 521 extending in a substantially horizontal direction, a rotating spindle 522 rotatably supported to the spindle housing 521, and a cutting blade 523 mounted on the rotating spindle 522 at a front end portion thereof. The rotating spindle 522 is adapted to be rotated in the direction shown by an arrow 523a by a servo motor (not shown) provided in the spindle housing 521. The cutting blade 523 is composed of a disk-shaped base 524 formed of aluminum and an annular cutting edge 525 mounted on one side surface of the base 524 along the outer circumference thereof. The annular cutting edge 525 is an electroformed diamond blade produced by bonding diamond abrasive grains having a grain size of 3 to 4 μm with nickel plating to the side surface of the outer circumferential portion of the base 524. For example, the cutting edge 525 has a thickness of 30 μm and an outer diameter of 52 mm.

The imaging means 53 is mounted on a front end portion of the spindle housing 521 and includes illuminating means for illuminating the workpiece, an optical system for capturing an area illuminated by the illuminating means, and an imaging device (CCD) for imaging the area captured by the optical system. An image signal output from the imaging means 53 is transmitted to control means (not shown).

In performing the division groove forming step by using the cutting apparatus 5 mentioned above, the semiconductor wafer 2 processed by the functional layer dividing step is placed on the chuck table 51 in the condition where the dicing tape 30 attached to the semiconductor wafer 2 is in contact with the chuck table 51 as shown in FIG. 8. Thereafter, suction means (not shown) is operated to hold the semiconductor wafer 2 through the dicing tape 30 on the chuck table 51 under suction (wafer holding step). Accordingly, the front side 21a of the functional layer 21 of the semiconductor wafer 2 held on the chuck table 51 is oriented upward. Although the annular frame 3 supporting the dicing tape 30 is not shown in FIG. 8, the annular frame 3 is held by suitable frame holding means provided on the chuck table 51. Thereafter, the chuck table 51 holding the semiconductor wafer 2 is moved to a position directly below the imaging means 53 by operating the feeding means (not shown).

In the condition where the chuck table 51 is positioned directly below the imaging means 53, an alignment operation is performed by the imaging means 53 and the control means (not shown) to detect a subject area of the semiconductor wafer 2 to be cut. In this alignment operation, the imaging means 53 images the two laser processed grooves 24 formed along each street 23 of the semiconductor wafer 2 by the functional layer dividing step. More specifically, the imaging means 53 and the control means perform image processing such as pattern matching for making the alignment of the cutting blade 523 and the two laser processed grooves 24 formed along each street 23 extending in a first direction on the functional layer 21 of the semiconductor wafer 2, thus performing the alignment of a cut area by the cutting blade 523 (alignment step). Similarly, the alignment of a cut area by the cutting blade 523 is performed for the other two laser processed grooves 24 formed along each street 23 extending in a second direction perpendicular to the first direction on the functional layer 21.

After performing the alignment step mentioned above to detect the two laser processed grooves 24 formed along each street 23 of the semiconductor wafer 2 held on the chuck table 51, the chuck table 51 is moved to a cut start position in the cut area by the cutting blade 523, thereby positioning one end (left end as viewed in FIG. 9A) of a predetermined one of the streets 23 on the right side of a position directly below the cutting blade 523 by a predetermined amount. Since the two laser processed grooves 24 formed along each street 23 are directly imaged by the imaging means 53 to detect the cut area in the alignment step mentioned above, the center position between the two laser processed grooves 24 formed along each street 23 can be reliably set so as to be opposed to the outer circumference of the cutting blade 523.

In the condition where the semiconductor wafer 2 held on the chuck table 51 is set at the cut start position in the cut area as described above, the cutting blade 523 is lowered from a standby position shown by a phantom line in FIG. 9A to a working position shown by a solid line in FIG. 9A as shown by an arrow Z1 in FIG. 9A. As shown in FIGS. 9A and 9C, this working position is set so that the lower end of the cutting blade 523 reaches the dicing tape 30 attached to the back side of the semiconductor wafer 2.

Thereafter, the cutting blade 523 is rotated in the direction shown by an arrow 523a in FIG. 9A at a predetermined rotational speed, and the chuck table 51 is moved in the direction shown by an arrow X1 in FIG. 9A at a predetermined feed speed. When the other end (right end as viewed in FIG. 9B) of the predetermined street 23 reaches a position on the left side of the position directly below the cutting blade 523 by a predetermined amount as shown in FIG. 9B, the movement of the chuck table 51 is stopped. As a result, a division groove 26 is formed between the outer side walls of the two laser processed grooves 24 formed along the predetermined street 23 so that the depth of the division groove 26 reaches the back side of the substrate 20 of the semiconductor wafer 2 as shown in FIG. 9D (division groove forming step).

Thereafter, the cutting blade 523 is raised from the working position to the standby position shown by a phantom line in FIG. 9B as shown by an arrow Z2 in FIG. 9B, and the chuck table 51 is next moved in the direction shown by an arrow X2 in FIG. 9B to the position shown in FIG. 9A. Thereafter, the chuck table 51 is moved in the direction (indexing direction) perpendicular to the sheet plane of FIG. 9A by an amount corresponding to the pitch of the streets 23, thereby aligning the cutting blade 523 with the next street 23 to be cut. In the condition where the cutting blade 523 is aligned with the next street 23 to be cut as mentioned above, the division groove forming step is performed similarly.

For example, the division groove forming step mentioned above is performed under the following processing conditions.

Cutting blade: outer diameter: 52 mm
thickness: 30 μm

Rotational speed of the cutting blade: 40000 rpm

Work feed speed: 50 mm/s

The division groove forming step mentioned above is performed similarly along all of the streets 23 of the semiconductor wafer 2. As a result, the semiconductor wafer 2 is cut along all of the streets 23 and thereby divided into the individual devices 22.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method for dividing a wafer into a plurality of individual devices along a plurality of crossing streets formed on a front side of said wafer, said wafer being composed of a substrate and a functional layer formed on the front side of said substrate, said individual devices being formed from said functional layer and partitioned by said streets, said wafer processing method comprising:
a functional layer dividing step of applying a laser beam along both sides of each street of said wafer to form two laser processed grooves spaced in parallel to each other, each laser processed groove having a depth reaching said substrate, thereby dividing said functional layer; and
a division groove forming step of forming a division groove in said functional layer and said substrate along each street so that said division groove extends along the center line between said two laser processed grooves formed along each street,
wherein the wavelength of said laser beam to be applied in said functional layer dividing step is set to 300 nm or less that is an absorption wavelength to a passivation film.

2. The wafer processing method according to claim 1, wherein said division groove forming step includes the step of applying a laser beam along the center line between said two laser processed grooves formed along each street, thereby forming said division groove in said functional layer and said substrate along each street.

3. The wafer processing method according to claim 2, wherein the wavelength of said laser beam to be applied in said functional layer dividing step is set to 266 nm, and the wavelength of said laser beam to be applied in said division groove forming step is set to 532 nm.
